(19) United States
(12) Patent Application Publication
(10) Pub. No.: US 2022/0045886 A1
(43) Pub. Date: Feb. 10, 2022

(54) Method For Processing A Stream Of Data In A Receiver Device

(71) Applicants: Commissariat A L'Energie Atomique et Aux Energies Alternatives, PARIS (FR); DAVEY BICKFORD, HERY (FR)

(72) Inventor: Valérian MANNONI, GRENOBLE CEDEX 09 (FR)

(21) Appl. No.: 17/299,228

(22) PCT Filed: Dec. 3, 2019
(86) PCT No.: PCT/FR2019/052902

§ 371 Date: Jun. 2, 2021

(30) Foreign Application Priority Data
Dec. 3, 2018 (FR) 1872208

(51) Int. Cl. H04L 25/49; H03M 5/12; H04L 1/00; F42D 1/05

(52) U.S. Cl. CPC H04L 25/4904; H03M 5/12; F42D 1/05; H04L 1/0046; H04L 1/006

(57) ABSTRACT

A method for processing, in a receiver device, a signal representative of a stream of data coded from a series of information units through coding using a predefined group of symbols to code each information unit of the series, comprises: —a step of receiving (E0) said signal, said signal having been sent by a sender device via a transmission channel, said received signal containing a sequence of symbols of predefined length, and —a step of combined equalization and decoding (E3) applied to said received signal (Ireceived), using a mesh (100) representing the transmission channel (3) and the coding that is used, the mesh (100) containing a number of nodes (101) representing states of the transmission channel (104), said states of the transmission channel (104) taking into account said coding that is used.

The present invention relates to a method for processing a data stream in a receiver device.

In particular, the data stream is coded by a coding using a predefined group of symbols for coding an information unit, such as a BiPhase coding or coding of the Manchester type.

The invention also relates to a receiver device implementing the processing method according to the invention.

The invention is applicable in particular to any communication system using a coding/decoding of the Manchester type.

For example, the invention is applicable in the field of pyrotechnics, in the communications between one or more detonators and a control console, these communications being capable of being of the wired or wireless type.

The electronic detonators and the control console communicate with one another, for example for exchanging commands or messages relating to the programming, diagnostics and firing of the electronic detonators.

When a bitstream (or stream of information units), representing the command or message, is to be transmitted over a transmission channel, among other things it is encoded to form an encoded data stream, then modulated to form a signal. This signal representing the encoded data stream is then transmitted over a transmission channel then received by a receiver device.

A type of coding often used by the electronic detonators for transmitting messages to the control console is BiPhase coding or Manchester type coding. By coding/decoding of the Manchester type is meant coding/decoding of the Manchester and Manchester differential type.

Coding of the Manchester type uses two symbols to code a bit or information unit. In particular, it uses two different consecutive symbols, which can be two symbols with opposite polarities (+1 or −1 for example). For example, a first pair of symbols “−1, +1” is used to code a “1” and a second pair of symbols “+1, −1” is used to code a “0”.

Each symbol can represent a voltage level, a transition between a low voltage level and a high voltage level representing a “1” and a transition between a high voltage level and a low voltage level representing a “0”.

The signal representative of an encoded data stream received by a transmitter device is thus formed by a sequence of symbols, each pair of symbols of the sequence representing an information unit.

During communications between a transmitter device and a receiver device, such as an electronic detonator and a control console respectively, and in particular when communication flow rates increase, interferences occur between symbols associated with the transmission channel.

In order to overcome this problem of interference between symbols, an equalization is implemented in the receiver, before decoding, on the signal received in the decoder device.

A type of equalization consists of reconstituting the stream of encoded data received in the sense of maximum likelihood, i.e. by exploiting the interdependence of the data items received and maximizing the likelihood thereof. This type of equalization has optimum performance but the complexity of implementation for data coded through coding using a predefined group of symbols, such as Manchester coding, is high.

This type of equalization can be implemented by means of a trellis representing or modelling the transmission channel. A trellis contains a set of nodes representing possible states of the signal transmitted via the transmission channel, the nodes being linked by branches or paths representing the possible transitions from one state to another. Each node contains two entry paths and two exit paths.

After equalization, the equalized symbols are decoded in order to obtain information units or information bits. Decoding is thus carried out on a reconstituted data stream, the probabilities associated with each symbol no longer being available. Thus there is a loss of information during decoding.

The aim of the present invention is to propose a method for processing a data stream in a receiver device making it possible to improve performance of reconstitution of the information received, while reducing the processing complexity.

To this end, according to a first aspect, the invention relates to a method for processing, in a receiver device, a signal representative of an encoded data stream based on a stream of information units through coding using a predefined group of symbols to code each information unit of the stream, the method containing:
a step of receiving said signal, said signal having been transmitted by a transmitter device via a transmission channel, said received signal containing a sequence of symbols of predefined length, and
a combined equalization and decoding step applied to said received signal, using a trellis representing the transmission channel and the coding used, the trellis containing a number of nodes representing states of the transmission channel, said states of the transmission channel taking into account said coding used.

Thus, during the equalization step, the coding of the signal transmitted via the transmission channel or communication channel is taken into account, and consequently at the end of this equalization step, the received signal is equalized and decoded. In other words, the equalization and decoding steps are both carried out by means of the trellis, this trellis representing the communication channel and the coding used on transmission of the signal.

Taking into account the coding during implementation of the equalization thus makes it possible to carry out the equalization and the decoding in a combined fashion, and consequently without losing the information of the probabilities associated with the equalized symbols and thus gaining in efficiency and performance.

In fact, it is preferable to retain the likelihoods (or probabilities) associated with each symbol, so as to be able to recombine successive symbols forming a possible group of symbols according to the coding used, or group of symbols capable of coding, according to the coding used, an information unit or bit.

The gain in efficiency and performance is obtained without thereby rendering the processing more complex, as only the possible states of the signal according to the coding used are taken into account in the trellis representing the communication channel.

Usually, this operation renders the receiver more complex. However, in the invention the opposite is the case; the complexity is reduced.

In fact, the nodes of the trellis represent possible states of the received signal. The signal is formed by a sequence of symbols containing predefined groups of signals, each predefined group of signals encoding an information bit or unit. Thus, as the nodes of the trellis or states of the channel correspond only to the possible states according to the coding used, the number of possible states of the signal is reduced with respect to a trellis representing a communication channel of the same length and used for an equalization in which the coding used is not taken into account.

Consequently, the complexity of the trellis utilized for equalization and decoding of the received data stream is reduced, the complexity of the receiver thus being reduced.

According to a characteristic, the stream of information units is coded in a BiPhase coding in order to form the encoded data stream.

Thus, the predefined group of symbols contains two different symbols with opposite polarity, each information bit or unit being encoded by two symbols. The symbols represent for example a voltage level with respectively opposite polarities.

The number of nodes is for example equal to the number of possible states of the transmission channel as a function of the coding used.

According to an example implementation, the number of nodes of the trellis is equal to Nₛₜ=M^{└L/2┘}, with the operator └.┘ representing the lower rounding, M the number of symbols used, i.e. the number of levels used for the coding or else number of states of the modulation or else the order of the modulation, and L the predefined length of the sequence of symbols, also called the length of the channel or number of coefficients thereof.

Thus, here for example, M=2 for Manchester coding where the symbols used are {−1; 1}.

According to the invention, in the case where M=2, then Nₛₜ=2^{└L/2┘}.

By way of illustration, in the invention, for a case called “disjoint”, then the number of nodes Nₛₜ=M^{L}.

By virtue of the invention, the number of nodes is therefore much smaller, and accordingly the complexity of the receiver is reduced.

The number of nodes of the trellis or of possible states of the signal is a function of the length of the transmission channel and of the number of symbols used during the coding of the stream of information units.

The communication channel has a length L where L is an integer being greater than or equal to unity. For example, the communication channel has a length (L) of four.

When the coding used is BiPhase or Manchester coding, the number of symbols used is two. The BiPhase coding structure provides for the symbols to be transmitted by pairs of symbols of opposite polarity. In other words, the possible predefined groups are formed by the set of symbols −1, +1 or the set of symbols +1, −1.

Thus, if for example the communication channel has a length L of four, the number of possible states of the communication channel or the number of nodes of the trellis is four.

In this example embodiment, with a communication channel of length L of four, the number of states of the communication channel is 4, while it would be 16 when the processing methods of the prior art are implemented.

According to a characteristic, the equalization step implements the Viterbi algorithm.

Applying this algorithm, known to a person skilled in the art, makes it possible to obtain very good equalization performances.

In an example implementation, the equalization step contains a step of determining an accumulated metric at each node of the trellis.

According to a characteristic, the equalization step contains a step of associating an initial metric corresponding to each node of the trellis with an instant in time, the metrics representing the likelihood of the received predefined groups of symbols with respect to the possible predefined groups of symbols according to the coding used.

This association of an initial metric makes it possible to associate initial metrics with each possible state of the channel according to the coding used.

When for example the coding used is BiPhase coding and the length of the communication channel is for example four, the initial state of the communication channel, i.e. before the encoded signal has been transmitted, is defined by the sequence of symbols [−1 −1 −1 −1], this state not containing possible predefined groups of symbols according to BiPhase coding.

The association thus makes it possible to associate metrics with each of the possible states in BiPhase coding, these states being formed respectively by the following sequences of symbols: [−1 +1 −1 +1], [−1 +1 +1 −1], [+1 −1 −1 +1] and [+1 −1 +1 −1].

The present invention relates to a second aspect, a receiver device containing:
means for receiving a signal transmitted by a transmitter device via a transmission channel, the signal being representative of an encoded data stream based on a stream of information units through coding using a predefined group of symbols for coding each information unit of the stream, said received signal containing a sequence of symbols of predefined length, and
equalization means for equalizing and decoding, in a combined manner, the signal received by said receiving means, by using a trellis representing the transmission channel and the coding used, the trellis containing a number of nodes representing states of the transmission channel, said states of the transmission channel taking into account said coding used.

According to a third aspect, the present invention relates to a control unit configured to establish communications with electronic detonators, the control unit containing a receiver device according to the invention implementing the method for processing a signal representative of an encoded data stream according to the invention.

According to a fourth aspect, the present invention relates to a system for firing at least one electronic detonator containing at least one control unit according to the invention and at least one electronic detonator linked to said control unit.

According to embodiments, said at least one electronic detonator and the control unit can be linked via wired or wireless communication means.

The receiver device, the control unit and the firing system of at least one electronic detonator have characteristics and advantages similar to those described above with respect to the processing method.

Other features and advantages of the invention will become apparent from the description hereinafter.

In the attached drawings, given by way of non-limitative example:

FIG. 1 is a diagram representing a transmitter and a receiver implementing the processing method according to the invention;

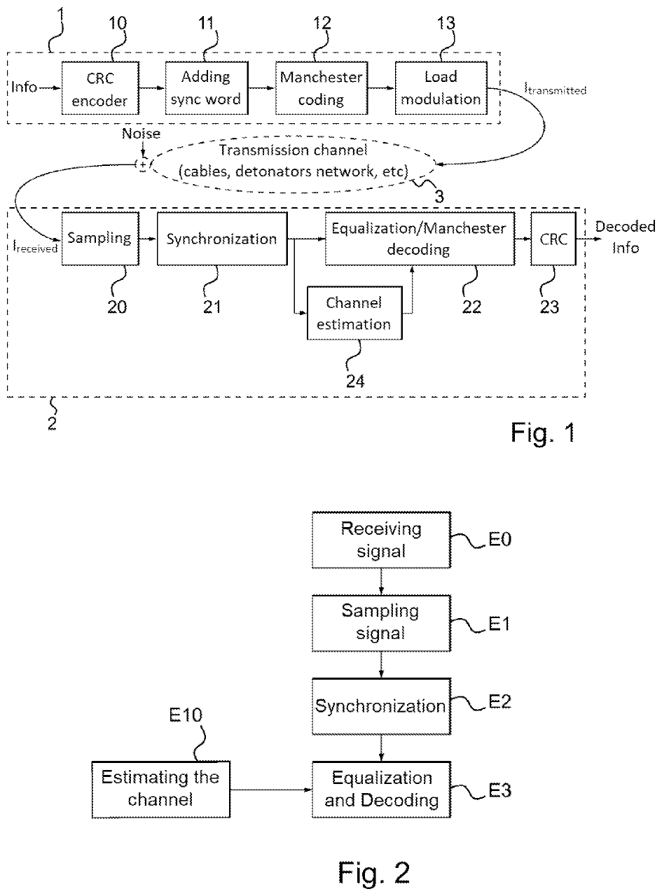

FIG. 2 illustrates a diagram representing steps of the processing method according to an embodiment;

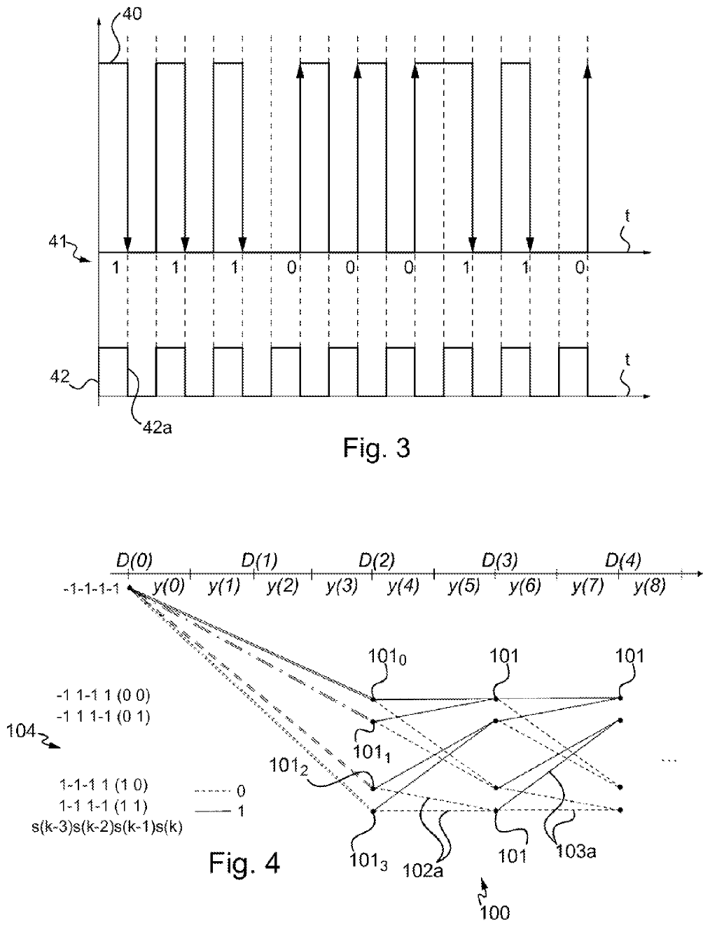

FIG. 3 represents an example of a signal representing an encoded data stream in BiPhase coding; and

FIG. 4 represents an example trellis used during the implementation of the processing method according to an embodiment.

FIG. 1 illustrates an electronic detonator 1 and a control unit or control console 2. The electronic detonator 1 is a transmitter device transmitting messages or commands to the control console 2 which constitutes a receiver device.

The processing method according to the invention is implemented in the receiver device 2. Steps of the method are illustrated in FIG. 2.

The processing method according to the invention will be described with reference to a firing system containing at least one electronic detonator 1 and a control console 2. However, the processing method can be implemented by any other receiver device implementing a decoding using a group of symbols, such as BiPhase coding or Manchester type coding.

It will be noted that in the following description, the coding used to form the encoded data stream is a BiPhase or Manchester coding. Thus, the group of symbols encoding an information bit contains two symbols.

However, other codings using predefined groups of symbols for encoding each information unit can be used.

The electronic detonator 1 and the control console 2 (or transmitter device and receiver device respectively) communicate with one another via a transmission channel or communication channel 3.

The communication channel 3 can be of wired type, the communications being governed for example by Ethernet standards such as 10Base-T, 10Base-5 or 10Base-2. The communication channel 3 can also be of wireless type, the transmitter device and the receiver device being for example linked by a short-distance radio link.

In an embodiment, the electronic detonator 1 or transmitter device contains a cyclic redundancy check (CRC) module 10. This CRC module 10 adds (for example by concatenation) to the stream of information units or bitstream to be sent to the receiver device 2, control codes or CRC codes making it possible to verify, on reception, the integrity of the bitstream received in the receiver device 2.

In the embodiment illustrated, the electronic detonator 1 also contains a synchronization module 11, a coding module 12 and a modulation module 13.

The bitstream to be transmitted is processed sequentially by the aforementioned modules to form a signal I_{transmitted} representing an encoded data stream in a coding such as the Manchester type coding.

The synchronization module 11 adds a synchronization preamble to the bitstream to be transmitted in order to be able to correctly reconstruct the bitstream in the receiver device 2.

Then, the coding module 12 codes the bitstream leaving the synchronization module 11 in a given coding. In the case of the electronic detonators, a widely used coding is Manchester coding. This coding, well known to a person skilled in the art, will be described with reference to FIG. 3.

Finally, once the data stream has been coded by the coding module 12, it is modulated by the modulation module 13. In this embodiment, this module implements a load modulation. This type of modulation varies for example a resistive load in an electronic circuit so as to generate, or not, a current on the line linking the electronic detonator and the control console so as to generate the signal I_{transmitted} to be transmitted.

On the receiver side, the control console 2 contains means for receiving signals (not shown), a sampling module 20 and a synchronization module 21 that are known to a person skilled in the art. FIG. 2 illustrates a diagram representing steps of the processing method implemented by the control console 2.

Once reception E0 of the signal is implemented by the receiving means, the received signal I_{received} is sampled in a sampling step E1 and synchronized in a synchronization step E2. Once sampled and synchronized, the received signal I_{received} is sent to an equalization module 22. The equalization module 22 implements, in a combined manner, in an equalization step E3, the equalization and decoding of the received signal I_{received} in order to obtain the bitstream in the decoded data stream without interference between symbols.

In the embodiment shown, once the encoded data stream is obtained, a cyclical redundancy control module 23 verifies the code-word in order to ensure the integrity of the received data.

In an embodiment, the receiver device 2 also contains estimation means 24 of the communication channel 3 configured to obtain the impulse response of the communication channel 3 through which the signal is transmitted. This impulse response is used during the equalization of the received signal. It will be noted that the estimation E10 of the channel is implemented prior to equalizing E3.

As indicated above, a type of coding used by the coding module 12 in the transmitter device 1 is Manchester coding.

This type of coding is widely used as it is simple to implement and signals coded in this way are resistant to losses of synchronization and to interference.

FIG. 3 illustrates a signal 40 representing an encoded data stream in Manchester coding. FIG. 3 also shows a clock signal 42 allowing synchronization between the transmitter device 1 and the receiver device 2.

The Manchester type coding or BiPhase coding is a coding of the synchronous type, i.e. apart from the data to be transmitted via a communication channel 3, the signals generated contain a synchronization clock signal that is necessary for decoding the data on reception.

As shown in FIG. 3, le coding module 12 of the transmitter device 1 generates a signal representative of an encoded data stream 40 based on a stream of information units or bitstream 41. The coding of the information units or bits is implemented by a transition of the signal. The coding of a “1” is implemented by a transition of the signal from a high level to a low level, and the coding of a “0” by a transition from a low level to a high level.

The coding module 12 in the transmitter device 1 is configured so that when the information bit to be coded is a “1”, the generated signal 40 comprises a high level followed by a low level, i.e. a descending transition is generated. When the information bit to be coded is a “0”, the generated signal 40 comprises a low level followed by a high level, i.e. an ascending transition is generated.

On the side of the receiver device 2, the start of the frame to be processed is obtained at the synchronization module 21, based on the encoded data stream received and sent to the equalization module 22 in order to be used for decoding the received encoded data stream. The synchronization module 21 is also configured to estimate the clock rate or frequency used on the transmitter side and to implement a sampling of the signal at the estimated clock rate or frequency.

Once the equalization module 22 receives the impulse response from the communication channel 3 originating from the estimation means 24 of the communication channel, and the encoded data stream, sampled and synchronized, it implements the equalization and decoding E3 of the encoded data stream.

In an embodiment, the equalization is implemented in the maximum likelihood sense. This type of equalization is known to a person skilled in the art and will not be described here. This type of equalization obtains optimal results in terms of performance.

According to an embodiment, the equalization can be implemented according to the Viterbi algorithm, also well known to a person skilled in the art.

This algorithm has very good equalization performance but requires the communication channel to be estimated.

In an embodiment, the communication channel is modelled by a finite impulse response filter. The impulse response can be rewritten as follows:

h=[h(0),h(1), . . . , h(L−1)]^{T}.

The signal received from the receiver device 2 can be written thus:

$$y ( k ) = {\sum }_{p = 0}^{L - 1} s ( k - p ) h ( p ) + b ( k )$$

Where y(k) represents the k^{th} sample of the received signal, s(k) being the k^{th} symbol transmitted and b(k) the zero-mean additive white Gaussian noise with variance σ².

As the impulse response of the channel is of length L, the signal has a memory of depth L. Thus, y(k) depends on the symbols s(k−L+1), s(k−L+2), . . . , s(k) and the following sample, y(k+1), depends on the symbols s(k−L+2), s(k−L+3), . . . , s(k+1). These two sequences of symbols contain L−1 common symbols, and there are therefore only two possibilities for passing from the first sequence to the second (the modulated symbols only being capable of adopting two values, namely +1 or −1).

According to other embodiments, other equalization algorithms can be used without requiring the communication channel to be estimated. However, the equalization obtained by this type of algorithm presents results that are broadly inferior with respect to those obtained when the Viterbi algorithm is used.

As is known to a person skilled in the art, the Viterbi algorithm uses a trellis to implement the equalization of the data stream.

FIG. 4 represents an example trellis 100 capable of being used by the equalization module 22 for implementing the equalization step of the processing method according to an embodiment of the present invention.

The equalization module 22 thus constructs a trellis 100 representing the communication channel 3. The trellis represents the state of the channel representative of the encoded data stream at different moments k.

Thus, the trellis 100 contains a set of nodes 101, each node 101 representing a state of the channel at a given moment. For example, a first node 1011 represents a first state, a second node 1012 represents a second state, a third node 1013 represents a third state and a fourth node 1014 represents a fourth state.

In the embodiment described, the communication channel 3 is considered to have a length L of 4. Thus each sample of the signal received is in reality a combination of 4 consecutive samples of the transmitted signal. The purpose of the equalization is then to recombine this signal so as to distinguish each sample of the transmitted signal.

In a case in which, unlike the invention, the decoding is implemented once the signal has been equalized, the number of states of the channel represented by a trellis would be M^{L}. In the case of Manchester coding, M is equal to 2, as 2 levels are used for the coding; consequently the number of states is equal to 16.

In the invention, the trellis incorporates Manchester coding in order to be able to implement the equalization and the decoding jointly.

Thus, only possible groups or pairs of symbols 104 in Manchester coding are represented in the trellis 100.

In Manchester coding, the symbols are always transmitted in pairs and are in opposite phase. Thus, when a logic “0” is transmitted, the symbols [+1 −1] are transmitted, and for a “1” the symbols [−1 +1] are transmitted. Thus for a state of the channel {01} the symbols [+1 −1 −1 +1] are transmitted.

As an information unit is encoded by two symbols, the number of states of the channel in the trellis is M^{└L/2┘}, i.e. 4 with L=4.

The possible states 104 of the channel correspond to the following sequences [s(k−3) s(k−2) s(k−1) s(k)]: [−1 +1 −1 +1], [−1 +1 +1 −1], [+1 −1 −1 +1] and [+1 −1 +1 −1], for L=4.

It will be noted that for one and the same length of the communication channel 3, the number of states of the channel and therefore the number of nodes of the trellis is reduced. Accordingly, the complexity of implementation of the algorithm used for equalization, such as the Viterbi algorithm, is reduced.

Each node 101 of the trellis has two entry paths 102a and two associated exit paths 103a. For the sake of clarity, in FIG. 4 the entry paths 102a and the exit paths 103a have been referenced for a single node 101.

According to the Viterbi algorithm, the accumulated metric at each node 101 of the trellis is determined.

In the invention, the accumulated metric for an information bit k can be determined according to the following formula:

$$D ( k ) = {\sum }_{k = 1}^{K} \{ {( y ( 2 k - 1 ) - z ( 2 k - 1 ) )}^{2} + {( y ( 2 k - 2 ) - z ( 2 k - 2 ) )}^{2} \}$$

It will be noted that z(k) is the signal filtered by the channel at instant k:

z(k)=Σₚ₌₀^{L-1}s(k−p)h(p).

The metric of a state (node) corresponding to the information bit k depends on the accumulated metric of the state of the channel at the preceding node, as well as the corresponding observation metric. This can be expressed in the following formula:

D(k)=D(k−1)+{(y(2k−1)−z(2k−1))²+(y(2k−2)−z(2k−2))²}

On the assumption that an additive white Gaussian noise is present, the joint probability density of the observation sequence y_{N}[y(0),y(1), . . . , y(N−1)]^{T} if the sequence z_{N}=[z(0),z(1), . . . , z(N−1)]^{T} was transmitted over a window of N samples in size is

$$p ( {y}_{N} \vert {z}_{N} ) = {\prod }_{n = 1}^{N} \frac{1}{\sqrt{2 π {σ}^{2}}} exp \{ - \frac{{( y ( n ) - z ( n ) )}^{2}}{2 {σ}^{2}} \}$$

The likelihood can be rewritten in the following manner:

$$p ( {y}_{N} \vert {z}_{N} ) = {( \frac{1}{\sqrt{2 π {σ}^{2}}} )}^{N} exp \{ - \frac{1}{2 {σ}^{2}} {\sum }_{n = 1}^{N} {( y ( n ) - z ( n ) )}^{2} \}$$

According to the Viterbi algorithm, the sequence z is determined, which maximizes the likelihood between two sequences of symbols, i.e. that which minimizes the accumulated metric D(N/2).

Thus, according to the Viterbi algorithm, among the entry paths 102a on a node 101, the path for which the accumulated metric D(k) is the smallest is the path selected. These operations are repeated over time for each state of the channel or node 101.

In an embodiment, an initial metric is associated with each node of the trellis at an instant in time. In an embodiment, the instant in time can be L−2, L being the length of the communication channel 3. If the length of the channel L is 4, the instant of time is K=2.

In fact, a particular initialization of the Viterbi algorithm is preferably considered. At instant “0”, the channel is in the initial state [−1−1 −1−1] (if L=4), as the channel has not yet been supplied with the Manchester modulated signal. Now, this state is no longer active subsequently, and it is therefore necessary to have a particular processing on initialization so as to pass from the initial state to the Nₛₜ=M^{└L/2┘} states actually operated subsequently.

The association of the initial metric at the nodes of the trellis with an instant in time makes it possible to implement the equalization step, starting from possible states of the channel according to the coding used.

In fact, when for example the coding used is BiPhase coding and the length of the communication channel is four, the initial state of the communication channel, i.e. before the encoded signal has been transmitted, is defined by the sequence of symbols [−1 −1 −1 −1]. This state does not contain possible predefined groups of symbols according to BiPhase coding.

Thus, initial metrics are associated with each possible state of the channel according to the coding used ([−1 +1 −1 +1], [−1 +1 +1 −1], [+1 −1 −1 +1] and [+1 −1 +1 −1]), for example L=4 and M=2, the symbol values being +1 or −1.

In the case of a channel length L=4, the initialization of the communication channel 3 can be implemented according to the following formulas:

$$D ( 2 , 0 ) = {\{ y ( 0 ) - [ - h ( 4 ) - h ( 3 ) - h ( 2 ) - h ( 1 ) - h ( 0 ) ] \}}^{2} + {\{ y ( 1 ) - [ - h ( 4 ) - h ( 3 ) - h ( 2 ) - h ( 1 ) + h ( 0 ) ] \}}^{2} + {\{ y ( 2 ) - [ - h ( 4 ) - h ( 3 ) - h ( 2 ) + h ( 1 ) - h ( 0 ) ] \}}^{2} + {\{ y ( 3 ) - [ - h ( 4 ) - h ( 3 ) + h ( 2 ) - h ( 1 ) + h ( 0 ) ] \}}^{2}$$

$$D ( 2 , 1 ) = {\{ y ( 0 ) - [ - h ( 4 ) - h ( 3 ) - h ( 2 ) - h ( 1 ) - h ( 0 ) ] \}}^{2} + {\{ y ( 1 ) - [ - h ( 4 ) - h ( 3 ) - h ( 2 ) - h ( 1 ) + h ( 0 ) ] \}}^{2} + {\{ y ( 2 ) - [ - h ( 4 ) - h ( 3 ) - h ( 2 ) + h ( 1 ) + h ( 0 ) ] \}}^{2} + {\{ y ( 3 ) - [ - h ( 4 ) - h ( 3 ) + h ( 2 ) + h ( 1 ) - h ( 0 ) ] \}}^{2}$$

$$D ( 2 , 2 ) = {\{ y ( 0 ) - [ - h ( 4 ) - h ( 3 ) - h ( 2 ) - h ( 1 ) + h ( 0 ) ] \}}^{2} + {\{ y ( 1 ) - [ - h ( 4 ) - h ( 3 ) - h ( 2 ) + h ( 1 ) - h ( 0 ) ] \}}^{2} + {\{ y ( 2 ) - [ - h ( 4 ) - h ( 3 ) + h ( 2 ) - h ( 1 ) - h ( 0 ) ] \}}^{2} + {\{ y ( 3 ) - [ - h ( 4 ) + h ( 3 ) - h ( 2 ) - h ( 1 ) + h ( 0 ) ] \}}^{2}$$

$$D ( 2 , 3 ) = {\{ y ( 0 ) - [ - h ( 4 ) - h ( 3 ) - h ( 2 ) - h ( 1 ) + h ( 0 ) ] \}}^{2} + {\{ y ( 1 ) - [ - h ( 4 ) - h ( 3 ) - h ( 2 ) + h ( 1 ) - h ( 0 ) ] \}}^{2} + {\{ y ( 2 ) - [ - h ( 4 ) - h ( 3 ) + h ( 2 ) - h ( 1 ) + h ( 0 ) ] \}}^{2} + {\{ y ( 3 ) - [ - h ( 4 ) + h ( 3 ) - h ( 2 ) + h ( 1 ) - h ( 0 ) ] \}}^{2}$$

Where D(2,0) corresponds to the initial metric at the instant in time k=2 for the node 1010 representing the state ([−1 +1 −1 +1], D(2,1) corresponds to the initial metric at the instant in time k=2 for the node 1011 representing the state [−1 +1 +1 −1], D(2,2) corresponds to the initial metric at the instant in time k=2 for the node 1013 representing the state [+1 −1 −1 +1] and D(2,3) corresponds to the initial metric at the instant in time k=2 for the node 1013 representing the state [+1 −1 +1 −1]).

1. A method for processing, in a receiver device, a signal (I_{received}) representative of an encoded data stream based on a stream of information units (info) through coding using a predefined group of symbols for coding each information unit of the stream (info), the method containing:
a step of receiving said signal (I_{received}), said signal (I_{received}) having been transmitted by a transmitter device via a transmission channel, said received signal containing a sequence of symbols of predefined length (L), and
a combined equalization and decoding step applied to said received signal (I_{received}), using a trellis representing the transmission channel and the coding used, the trellis containing a number of nodes representing states of the transmission channel, said states of the transmission channel taking into account said coding used.

2. The method according to claim 1, characterized in that the number of nodes is equal to the number of possible states of the transmission channel as a function of the coding used.

3. The method according to claim 1, characterized in that the number of nodes of the trellis is equal to Nₛₜ=M└L/2┘, with the operator └.┘ representing the lower rounding, M the number of symbols used, and L the predefined length of the sequence of symbols.

4. The method according to claim 1, characterized in that the stream of information units (info) is coded in a BiPhase coding in order to form the encoded data stream (I_{transmitted}).

5. The method according to claim 1, characterized in that the equalization step implements the Viterbi algorithm.

6. The method according to claim 1, characterized in that the equalization step contains a step of associating an initial metric corresponding to each node of the trellis with an instant in time, the metrics representing the likelihood of the received predefined groups of symbols with respect to the possible predefined groups of symbols according to the coding used.

7. The method according to claim 1, characterized in that it also contains an estimation step of the transmission channel implemented beforehand in said equalization step.

8. A receiver device containing:
receiving means of a signal (I_{received}) having been transmitted by a transmitter device via a transmission channel, the signal (I_{received}) being representative of an encoded data stream based on a stream of information units (info) through coding using a predefined group of symbols for coding each information unit of the stream (info), said received signal (I_{received}) containing a sequence of symbols of predefined length (L), and
equalization means for equalizing and decoding, in a combined manner, the signal received (I_{received}) by said receiving means, by using a trellis representing the transmission channel and the coding used, the trellis containing a number of nodes representing states of the transmission channel, said states of the transmission channel taking into account said coding used.

9. An electronic detonator containing the receiver device according to claim 8.

10. A system for firing at least one electronic detonator containing the electronic detonator according to claim 9 and a control unit linked to said at least one electronic detonator.
